(19) United States
(12) Patent Application Publication
(10) Pub. No.: US 2026/0213772 A1
(43) Pub. Date: Jul. 23, 2026

(54) ENHANCED PCI EXPRESS (PCIE) FORWARD ERROR CORRECTION (FEC)

(71) Applicant: Microchip Technology Incorporated, Chandler, AZ (US)

(72) Inventor: Peter Graumann, Calgary (CA)

(21) Appl. No.: 19/372,079

(22) Filed: Oct. 28, 2025

Related U.S. Application Data
(60) Provisional application No. 63/747,783, filed on Jan. 21, 2025.

(51) Int. Cl. H03M 13/37

(52) U.S. Cl. CPC H03M 13/373

(57) ABSTRACT

Disclosed herein are apparatus, system, method, and computer-readable medium aspects for error correction in a PCI Express (PCIe) Forward Error Correction (FEC) system. An example method may include receiving an FEC block comprising interleaved Reed-Solomon (RS) codewords, decoding the FEC block using a standard decoder to correct up to three successive RS symbol errors, and if the standard decoder fails, attempting error correction using one or more parallel decoders, comprising at least a 4-burst decoder to correct a single burst error spanning four RS symbols. The method may include selecting a corrected FEC block from an output of one of the standard decoder and the one or more parallel decoders based on successful error correction. The one or more parallel decoders can further comprise a 5-burst decoder and a 6-burst decoder.

### CROSS-REFERENCE TO RELATED APPLICATION

The present application claims priority from U.S. Provisional Patent Application No. 63/747,783, filed Jan. 21, 2025, which is incorporated herein by reference in its entirety.

### TECHNICAL FIELD

The present disclosure relates generally to error correction techniques in high-speed communication systems, and more specifically to enhanced PCI Express (PCIe) Forward Error Correction (FEC).

### SUMMARY

According to an aspect of one or more examples, there is provided an apparatus for error correction in a PCI Express (PCIe) Forward Error Correction (FEC) system. The apparatus may include a standard decoder to correct up to three successive Reed-Solomon (RS) symbol errors using interleaved m8, t1 RS decoders, one or more parallel decoders, each to correct burst error patterns that may exceed the correction capability of the standard decoder, including at least a 4-burst decoder to correct a single burst error spanning four RS symbols, and a multiplexer to select a corrected FEC block from one of the decoders based on successful error correction. The standard decoder may operate on blocks of 256 bytes, each including interleaved RS codewords. The 4-burst decoder may use erasure decoding to correct two errors in a third RS codeword based on error locations from two correctly decoded RS codewords. The one or more parallel decoders may further include a 5-burst decoder to correct a single burst error spanning five RS symbols. The 5-burst decoder may identify error locations using one correctly decoded RS codeword and perform erasure decoding on the remaining two RS codewords. The 5-burst decoder may apply a +1, −1 error propagation pattern characteristic of PAM4 burst errors to correct neighboring symbols. The one or more parallel decoders may further include a 6-burst decoder to correct a single burst error spanning six RS symbols. The 6-burst decoder may identify potential burst error locations using a +1, −1 error propagation pattern and apply symbol corrections before performing RS decoding. The multiplexer may select the output from the decoder that provides successful error correction verified by an outer codeword. The apparatus may also include additional decoders to correct burst errors spanning seven or more RS symbols. The outer codeword may provide CRC verification after inner codes have performed corrections to correct up to four errors across the FEC block. The standard decoder, parallel decoders, and multiplexer may be implemented in hardware, firmware, or a combination thereof.

According to an aspect of one or more examples, there is provided a method for error correction in a PCI Express (PCIe) Forward Error Correction (FEC) system. The method may include receiving an FEC block comprising interleaved Reed-Solomon (RS) codewords, decoding the FEC block using a standard decoder to correct up to three successive RS symbol errors, if the standard decoder fails, attempting error correction using one or more parallel decoders, including at least a 4-burst decoder to correct a single burst error spanning four RS symbols, and selecting the corrected FEC block from the output of one of the decoders based on successful error correction. The operation of decoding with the standard decoder may include applying three interleaved m8, t1 RS decoders to the FEC block. The 4-burst decoder may apply erasure decoding to correct errors in a third RS codeword based on error locations identified in two correctly decoded RS codewords. The one or more parallel decoders may further include a 5-burst decoder to correct a single burst error spanning five RS symbols. The 5-burst decoder may use a correctly decoded RS codeword to erase symbols in the remaining two RS codewords and perform erasure decoding on the erasures. The 5-burst decoder may apply a +1, −1 error propagation pattern characteristic of PAM4 burst errors to correct adjacent symbols in the erroneous RS codewords. The one or more parallel decoders may further include a 6-burst decoder to correct a single burst error spanning six RS symbols. The 6-burst decoder may identify potential burst error locations using a +1, −1 error propagation pattern and apply symbol corrections before attempting RS decoding. The method may also include verifying the correction of the FEC block using an outer codeword for CRC checking. The corrected FEC block may be selected based on the successful verification of both inner RS codewords and the outer codeword. The method may also include correcting FEC blocks with burst errors spanning seven or more RS symbols using additional parallel decoders. The operations may be implemented using hardware, firmware, or a combination of both, for high-speed PCIe communication systems.

According to an aspect of one or more examples, there is provided an apparatus for error correction in a PCI Express (PCIe) Forward Error Correction (FEC) system. The apparatus may include a standard decoder to correct up to three successive Reed-Solomon (RS) symbol errors, one or more parallel decoders, each to correct burst error patterns that may exceed the correction capability of the standard decoder, and a multiplexer to select a corrected FEC block from one of the decoders based on successful error correction.

### BRIEF DESCRIPTION OF DRAWINGS

FIG. 1 shows a block diagram of a PCI Express (PCIe) Forward Error Correction (FEC) system, according to one or more examples.

FIG. 2A shows a graphical representation of a (4, 1) error with four contiguous 8-bit Reed-Solomon (RS) symbol errors in a single burst, according to one or more examples.

FIG. 2B shows a graphical representation of a (6, 1) error with six contiguous 8-bit RS symbol errors in a single burst, according to one or more examples.

FIG. 2C shows a graphical representation of a (5, 1) error with five contiguous 8-bit RS symbol errors in a single burst, according to one or more examples.

FIG. 3 is a flowchart of a method for error correction in a PCI Express (PCIe) Forward Error Correction (FEC) system, according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

High-speed communication systems, such as PCI Express (PCIe) Gen7, face significant challenges in maintaining reliable data transmission under stringent operational conditions. The PCIe Gen7 specification requires a First Symbol Error Rate (FSER) of 1×10⁻⁶ or lower, reflecting the level of reliability demanded by modern applications. This FSER specification accounts for the burst-error behavior of Serializer/Deserializer (SerDes) links, where an initial error frequently leads to a sequence of consecutive errors. Such burst errors are particularly difficult to address, as they often exceed the error correction capabilities of existing systems.

Meeting the FSER requirement becomes increasingly difficult in compliance channels with up to 36 dB insertion loss (IL) under the influence of cross-talk noise and variations in process, voltage, and temperature (PVT). Furthermore, to ensure robustness and scalability, systems may also support channels with higher insertion losses of up to 40 dB, which surpass the standard compliance requirements. These demanding conditions strain the capabilities of the physical layer (PHY), as improving its performance often involves increases in power consumption, design complexity, and area, leading to diminishing returns.

Existing Forward Error Correction (FEC) mechanisms are also limited in their ability to address the burst-error properties of modern high-speed SerDes links. While the standard PCIe FEC can correct up to nine consecutive PAM4 (Pulse-Amplitude Modulation, 4 levels) symbol errors, corresponding to three 8-bit Reed-Solomon (RS) symbol errors, longer burst errors remain uncorrectable. Error burst patterns, such as those with four or more contiguous symbol errors, are commonly encountered in challenging channels and exceed the correction capabilities of standard decoders. As a result, the inability to correct these longer bursts leads to increased block error rates and reduced overall system performance. Therefore, there exists a need for an enhanced error correction mechanism that can address longer burst errors while maintaining compliance with stringent FSER requirements, thereby alleviating the burden on the PHY and enabling reliable operation across a broader range of channel conditions in PCIe Gen7 systems.

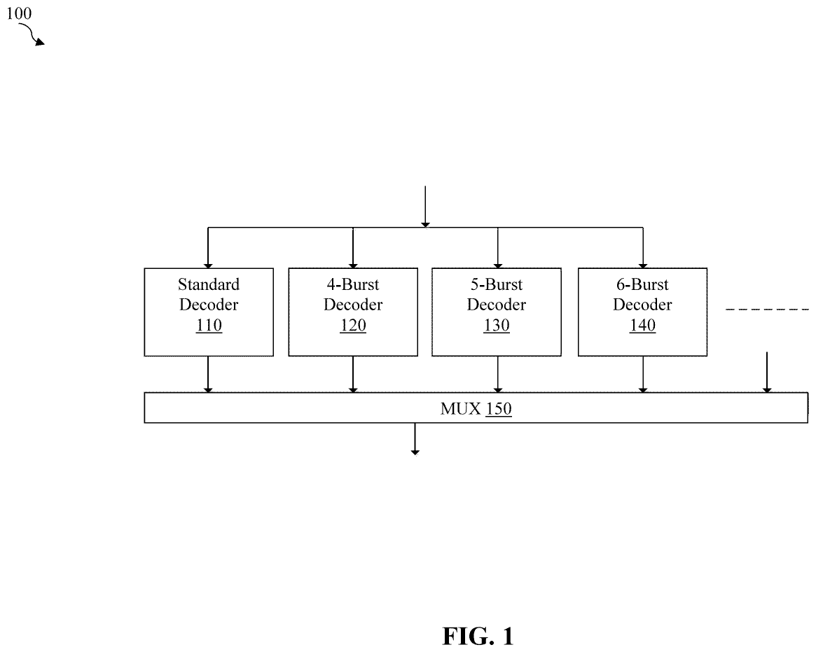

FIG. 1 shows a block diagram of a PCI Express (PCIe) Forward Error Correction (FEC) system 100 according to one or more examples. The PCIe FEC system 100 may enhance error correction capabilities by incorporating a standard decoder 110 alongside one or more additional parallel decoders (in the non-limiting example of FIG. 1, three parallel decoders are shown), each customized to handle specific, commonly occurring error patterns. These parallel decoders may address longer and more complex burst-error events than those correctable by the standard PCIe FEC, improving performance across challenging channel conditions.

The standard decoder 110 may include three interleaved (m8, t1) Reed-Solomon (RS) decoders. Each RS decoder may operate on 8-bit symbols (m8) and may correct a single random symbol error, denoted as t1. Each RS symbol may represent four PAM4 symbols, and the ability of each RS decoder to correct a single symbol error may translate to correcting errors within the PAM4 symbol structure. The interleaving scheme employed by the standard decoder 110 may allow it to handle burst errors that affect up to three successive RS symbols. Since each RS symbol corresponds to four PAM4 symbols, the standard decoder 110 may correct any burst error of up to nine PAM4 symbols. However, when a burst error exceeds nine PAM4 symbols, resulting in four or more RS symbols in error, the standard decoder 110 may be unable to correct the block. To ensure reliability, the results from the standard decoder 110 may be tested against the cyclic redundancy check (CRC) as defined in the standard. The CRC check may verify the correctness of all decoded outputs. The inputs to the standard decoder 110 may include the received FEC block, which contain error patterns, and the output of the standard decoder 110 may be the decoded FEC block if it is correctable. Otherwise, the standard decoder 110 may provide an indication that the block is uncorrectable.

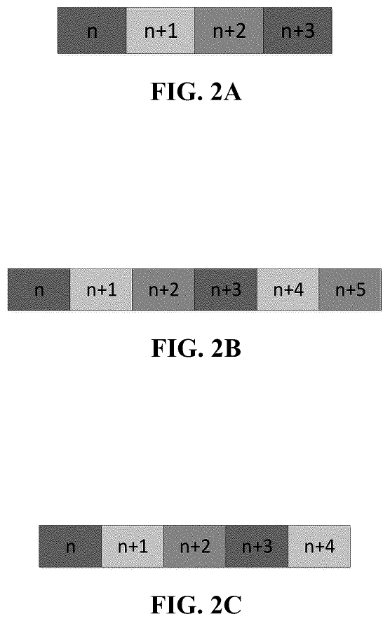

The 4-burst decoder 120, which may handle (4, 1) errors (shown in FIG. 2A), may address single burst errors that span four RS symbols. In these cases, two of the inner RS decoders may encounter a single error (e.g., positions n+1 and n+2, respectively, in FIG. 2A) and decode correctly, while a third RS decoder may have two errors (e.g., n and n+3 in FIG. 2A). The 4-burst decoder 120 may use the error locations identified by the two correctly decoded inner RS decoders to deduce the two error locations in the third RS decoder. These locations may be marked as erasures, and the third RS decoder may apply erasure decoding to correct the errors. Erasure decoding may double the correction capability, making it possible to recover the block. After decoding, the outer codeword may be tested using the CRC to validate the correction. The inputs to the 4-burst decoder 120 may include the FEC block containing a (4, 1) error pattern and the error locations derived from the two correctly decoded inner RS decoders. If the error pattern matches (4, 1), the output may be a fully corrected FEC block. Otherwise, the 4-burst decoder 120 may signal that the block is uncorrectable.

The 5-burst decoder 130 may handle (5, 1) errors (shown in FIG. 2C), which involve a single burst error spanning five RS symbols. In this scenario, one of the inner RS decoders may encounter a single error (e.g., position n+2 in FIG. 2C) and decode correctly, while the other two inner RS decoders each have two errors (e.g., n and n+3 and n+1 and n+4, respectively, in FIG. 2C). The 5-burst decoder 130 may use the error location from the correctly decoded inner RS decoder to erase two symbols in the remaining two RS decoders. These erasures may then be decoded using (t1) erasure decoding. Alternatively, the (+1, −1) error propagation pattern characteristic of PAM4 bursts may be leveraged to correct two neighboring symbols in each of the two inner RS decoders. Once these corrections are applied, standard (t1) decoding may be performed on the remaining blocks to verify correctness. The inputs to the 5-burst decoder 130 may include the FEC block with a (5, 1) error pattern and the error location from the correctly decoded inner RS decoder. The output may be a fully corrected FEC block if the error pattern matches (5, 1). Otherwise, the decoder may signal an uncorrectable block.

The 6-burst decoder 140 may correct (6, 1) errors (shown in FIG. 2B), where a single burst error spans six RS symbols. In this case, none of the inner RS decoders can provide reliable error location information because all three encounter two errors (e.g., positions n and n+3, n+1 and n+4, and n+2 and n+5, respectively, in FIG. 2B). Instead, the 6-burst decoder 140 may rely on the PAM4 (+1, −1) error propagation pattern to identify likely burst error locations. Once candidate locations are identified, the inner symbols (e.g., n+1, n+2, n+3, and n+4 in FIG. 2B) within the burst may be corrected by reversing the (+1, −1) error propagation, and (t1) RS decoding may be attempted on the two remaining decodes (e.g., n and n+5 in FIG. 2B). Due to the complexity of (6, 1) errors, multiple parallel decoder structures may be used to trial different potential error scenarios within the FEC block. The inputs may include the FEC block with a (6, 1) error pattern, and the output may be the corrected block if the error pattern matches (6, 1). Otherwise, an uncorrectable block signal may be generated.

Finally, the system 100 may employ a multiplexer (MUX) 150 to combine the outputs of the standard decoder 110 and the 4-burst, 5-burst, and 6-burst decoders 120, 130, and 140. The MUX 150 may receive the decoded outputs and their respective error correction status signals, selecting the first successfully decoded block that passes the cyclic redundancy check (CRC). This operation may ensure that the output is both corrected and validated for correctness. If none of the decoded blocks pass the CRC check or if multiple blocks pass the check, the block may be deemed uncorrectable. This approach may ensure that the most appropriate decoder processes the FEC block, achieving high error correction performance while maintaining compatibility with PCIe standards. Although FIG. 1 depicts the standard, 4-burst, 5-burst, and 6-burst decoders 110, 120, 130, and 140, the architecture may be extensible, and additional decoders to handle burst errors spanning seven or more RS symbols and other complex cases can also be implemented. The output of the MUX 150 may be the final, corrected FEC block or an indication that the block remains uncorrectable if none of the decoders successfully handle the error pattern.

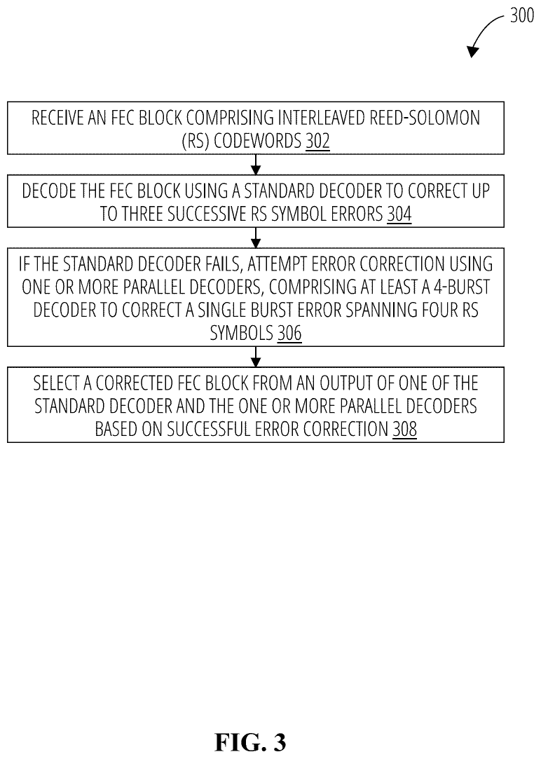

FIG. 3 is a flowchart for a method 300 for error correction in a PCI Express (PCIe) Forward Error Correction (FEC) system, according to various examples. It is to be appreciated that not all steps are needed to perform the disclosure provided herein. Further, some of the steps can be performed simultaneously, or in a different order than shown in FIG. 3, as will be understood by a person of ordinary skill in the art.

In operation 302, an FEC block comprising interleaved Reed-Solomon (RS) codewords is received. In operation 304, the FEC block is decoded using a standard decoder to correct up to three successive RS symbol errors. Using the standard decoder to decode can include applying three interleaved m8, t1 RS decoders to the FEC block.

In operation 306, if the standard decoder fails, error correction is attempted using one or more parallel decoders. The one or more parallel decoders comprises at least a 4-burst decoder to correct a single burst error spanning four RS symbols. The 4-burst decoder can apply erasure decoding to correct errors in a third RS codeword based on error locations identified in two correctly decoded RS codewords.

The one or more parallel decoders can also include a 5-burst decoder to correct a single burst error spanning five RS symbols. The 5-burst decoder can use a correctly decoded RS codeword to identify error locations, and perform erasure decoding on a remaining two RS codewords. The 5-burst decoder can apply a +1, −1 error propagation pattern characteristic of PAM4 burst errors to correct adjacent symbols in erroneous RS codewords.

The one or more parallel decoders can further include a 6-burst decoder to correct a single burst error spanning six RS symbols. The 6-burst decoder can identify potential burst error locations using a +1, −1 error propagation pattern and applies symbol corrections before attempting RS decoding.

In operation 308, a corrected FEC block is selected from an output of one of the standard decoder and the one or more parallel decoders based on successful error correction. The corrected FEC block can be selected based on successful verification of both inner RS codewords and an outer codeword.

Method 300 can further include verifying correction of the FEC block using an outer codeword for CRC checking. Method 300 can also include correcting FEC blocks with burst errors spanning seven or more RS symbols using additional parallel decoders.

Various examples have been disclosed herein, in connection with the above description and the drawings. It will be understood that it would be unduly repetitious to literally describe and illustrate every combination and subcombination of these examples. Accordingly, all examples can be combined in any way or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. An apparatus for error correction in a PCI Express (PCIe) Forward Error Correction (FEC) system, the apparatus comprising:
a standard decoder to correct up to three successive Reed-Solomon (RS) symbol errors, the standard decoder comprising interleaved m8, t1 RS decoders;
one or more parallel decoders, to correct specific burst error patterns exceeding a correction capability of the standard decoder, comprising at least a 4-burst decoder to correct a single burst error spanning four RS symbols; and
a multiplexer to select a corrected FEC block from one of the standard decoder and the one or more parallel decoders based on successful error correction.

2. The apparatus of claim 1, wherein the standard decoder is configured to operate on blocks of 256 bytes, each comprising interleaved RS codewords.

3. The apparatus of claim 1, wherein the 4-burst decoder is configured to use erasure decoding to correct two errors in a third RS codeword based on error locations from two correctly decoded RS codewords.

4. The apparatus of claim 1, wherein the one or more parallel decoders further comprises a 5-burst decoder to correct a single burst error spanning five RS symbols, and wherein the 5-burst decoder is configured to identify error locations using a single correctly decoded RS codeword and perform erasure decoding on a remaining two RS codewords.

5. The apparatus of claim 4, wherein the 5-burst decoder is configured to apply a +1, −1 error propagation pattern characteristic of PAM4 burst errors to correct neighboring symbols.

6. The apparatus of claim 1, wherein the one or more parallel decoders further comprises a 6-burst decoder to correct a single burst error spanning six RS symbols, and wherein the 6-burst decoder is configured to identify potential burst error locations using a +1, −1 error propagation pattern and apply symbol corrections before performing RS decoding.

7. The apparatus of claim 1, wherein the multiplexer is to select the corrected FEC block from the standard decoder, the 4-burst decoder, a 5-burst decoder, or a 6-burst decoder that provides successful error correction verified by an outer codeword.

8. The apparatus of claim 7, wherein the outer codeword provides CRC verification capability to correct up to four errors across the FEC block.

9. The apparatus of claim 1, the apparatus further comprises additional decoders to correct burst errors spanning seven or more RS symbols.

10. The apparatus of claim 1, wherein the standard decoder, the one or more parallel decoders, and the multiplexer are implemented in hardware, firmware, or a combination of hardware and firmware.

11. A method for error correction in a PCI Express (PCIe) Forward Error Correction (FEC) system, the method comprising:
receiving an FEC block comprising interleaved Reed-Solomon (RS) codewords;
decoding the FEC block using a standard decoder to correct up to three successive RS symbol errors;
if the standard decoder fails, attempting error correction using one or more parallel decoders, comprising at least a 4-burst decoder to correct a single burst error spanning four RS symbols; and
selecting a corrected FEC block from an output of one of the standard decoder and the one or more parallel decoders based on successful error correction.

12. The method of claim 11, wherein decoding using the standard decoder comprises applying three interleaved m8, t1 RS decoders to the FEC block.

13. The method of claim 11, wherein the 4-burst decoder applies erasure decoding to correct errors in a third RS codeword based on error locations identified in two correctly decoded RS codewords.

14. The method of claim 11, wherein the one or more parallel decoders further comprises a 5-burst decoder to correct a single burst error spanning five RS symbols, and wherein the 5-burst decoder uses a correctly decoded RS codeword to identify error locations, and perform erasure decoding on a remaining two RS codewords.

15. The method of claim 14, wherein the 5-burst decoder applies a +1, −1 error propagation pattern characteristic of PAM4 burst errors to correct adjacent symbols in erroneous RS codewords.

16. The method of claim 11, wherein the one or more parallel decoders further comprises a 6-burst decoder to correct a single burst error spanning six RS symbols, and wherein the 6-burst decoder identifies potential burst error locations using a +1, −1 error propagation pattern and applies symbol corrections before attempting RS decoding.

17. The method of claim 11, the method further comprising verifying correction of the FEC block using an outer codeword for CRC checking.

18. The method of claim 11, wherein the corrected FEC block is selected based on successful verification of both inner RS codewords and an outer codeword.

19. The method of claim 11, the method further comprising correcting FEC blocks with burst errors spanning seven or more RS symbols using additional parallel decoders.

20. An apparatus for error correction in a PCI Express (PCIe) Forward Error Correction (FEC) system, the apparatus comprising:
a standard decoder to correct up to three successive Reed-Solomon (RS) symbol errors;
one or more parallel decoders, to correct specific burst error patterns exceeding a correction capability of the standard decoder; and
a multiplexer to select a corrected FEC block from one of the standard decoder and the one or more parallel decoders based on successful error correction.
